(19) United States
(12) Patent Application Publication
(10) Pub. No.: US 2008/0225501 A1
(43) Pub. Date: Sep. 18, 2008

(54) Printed circuit board and manufacturing method thereof

(76) Inventors: Chung-Woo Cho, Suwon-si (KR); Chang-Sup Ryu, Yongin-si (KR); Soon-Jin Cho, Suwon-si (KR); Seung-Chul Kim, Cheongiu-si (KR)

Correspondence Address: STAAS & HALSEY LLP, SUITE 700, 1201 NEW YORK AVENUE, N.W., WASHINGTON, DC, 20005, US

(21) Appl. No.: 12/076,274

(22) Filed: Mar. 14, 2008

(30) Foreign Application Priority Data
Mar. 12, 2007 (KR) 10-2007-0124567

(51) Int. Cl. H05K 7/10; H01K 3/10

(52) U.S. Cl. 361/767; 29/852

(57) ABSTRACT

A printed circuit board and a manufacturing method thereof are disclosed. The printed circuit board, which includes a first insulation layer, a first via that penetrates the first insulation layer, and a first pad formed on one surface of the first insulation layer, where a whole of or a portion of the first pad is buried in the first via, has a portion of or the whole of the pad buried in the via, so that the contact area between the pad and the via may be increased, and the printed circuit board can be given greater reliability.

### CROSS-REFERENCE TO RELATED APPLICATIONS

This application claims the benefit of Korean Patent Application No. 10-2007-0124567 filed with the Korean Intellectual Property Office on Dec. 3, 2007, the disclosure of which is incorporated herein by reference in its entirety.

### BACKGROUND

1. Technical Field

The present invention relates to a printed circuit board and a manufacturing method for the printed circuit board.

2. Description of the Related Art

In a printed circuit board, vias may be formed in an insulation for interconnection between layers, for which laser drilling is mainly used.

That is, to interconnect an upper and lower layer, holes are formed in the insulation using a laser drill, after which a desmearing process is performed to remove smears and insulation residue. Then, a conductive material is filled inside the processed holes, using electroless chemical copper plating and electroplating, so that the upper and lower layers are interconnected.

FIG. 1 is a cross-sectional view of a printed circuit board according to the related art. In FIG. 1, there are illustrated a substrate 1, circuit patterns 2, 6, a pad 3, an insulation layer 4, and a via 5.

In a printed circuit board according to the related art, referring to FIG. 1, the upper surface of the pad 3 is formed wider than the lower surface of the via 5, so that the pad 3 and the via 5 contact each other by only one surface. According to the related art, in order-to secure a particular contact area between the via 5 and the pad 3, the pad 3 and via 5 have to be formed to correspondingly wide areas, making it difficult to implement fine pitch.

As such, in the structure of the printed circuit board according to the related art, problems of defective interconnection due to smears and insulation residue, problems in reliability due to degraded adhesion between pads 3 and vias 5, and problems of crevices are becoming important issues to be resolved.

Here, the problem of degraded adhesion between vias 5 and pads 3, and the problem of crevices can basically be seen as structural problems of the vias and pads.

### SUMMARY

An aspect of the invention is to provide a printed circuit board and a method of manufacturing the printed circuit board, in which a portion or the whole of a pad is buried in a via, so that the contact area between the pad and the via may be increased, to provide a printed circuit board with greater reliability.

One aspect of the invention provides a printed circuit board, which includes a first insulation layer; a first via that penetrates the first insulation layer; and a first pad formed on one surface of the first insulation layer, where a whole of or a portion of the first pad is buried in the first via.

The printed circuit board may further include a second pad formed on the other surface of the first insulation layer in a position corresponding with a position of the first via; a second insulation layer stacked over the other surface of the first insulation layer; and a second via that penetrates the second insulation layer, where a whole of or a portion of the second pad may be buried in the second via.

Another aspect of the invention provides a method of manufacturing a printed circuit board. The method includes providing a first insulation layer, on a surface of which a first pad is formed; processing a first hole from the other surface of the first insulation layer, such that a side of the first pad is exposed; and filing a conductive material in the first hole.

Here, filing the conductive material can include forming a seed layer on an inside of the first hole and the other surface of the first insulation layer; forming a patterned plating resist over the other surface of the first insulation layer; and performing electroplating. A depth of the first hole can be substantially equal to a depth of the first insulation layer.

Also, additional operations can be performed, such as forming a second pad on the other surface of the first insulation layer in a position corresponding with a position of the first hole; stacking a second insulation layer over the other surface of the first insulation layer; processing a second hole from the other surface of the second insulation layer, such that a side of the second pad is exposed; and filling a conductive material in the second hole.

The operation of processing the first hole may be performed by laser drilling.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross-sectional view of a printed circuit board according to the related art.

FIG. 2, FIG. 3, and FIG. 4 are cross-sectional views of a printed circuit board according to an aspect of the present invention.

FIG. 5 is a flowchart illustrating a method of manufacturing a printed circuit board according to another aspect of the present invention.

FIG. 6, FIG. 7, FIG. 8, FIG. 9, and FIG. 10 are cross-sectional views representing a flow diagram for a method of manufacturing a printed circuit board according to a first disclosed embodiment based on another aspect of the present invention.

FIG. 11, FIG. 12, FIG. 13, FIG. 14, and FIG. 15 are cross-sectional views representing a flow diagram for a method of manufacturing a printed circuit board according to a second disclosed embodiment based on another aspect of the present invention.

### DETAILED DESCRIPTION

As the invention allows for various changes and numerous embodiments, particular embodiments will be illustrated in drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

While such terms as “first,” “second,” etc., may be used to describe various elements, such elements must not be limited to the above terms. The above terms are used only to distinguish one element from another.

The terms used in the present application are merely used to describe particular embodiments, and are not intended to limit the present invention. An expression used in the singular encompasses the expression of the plural, unless it has a clearly different meaning in the context. In the present application, it is to be understood that the terms such as “including” or “having,” etc., are intended to indicate the existence of the features, numbers, steps, actions, elements, parts, or combinations thereof disclosed in the specification, and are not intended to preclude the possibility that one or more other features, numbers, steps, actions, elements, parts, or combinations thereof may exist or may be added.

Embodiments of the printed circuit board and manufacturing method thereof according to certain aspects of the invention will now be described below in more detail with reference to the accompanying drawings. Those components that are the same or are in correspondence are rendered the same reference numeral regardless of the figure number, and redundant explanations are omitted.

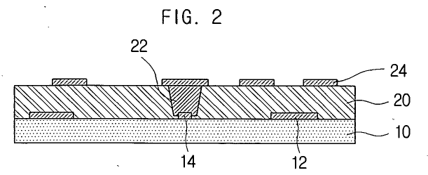

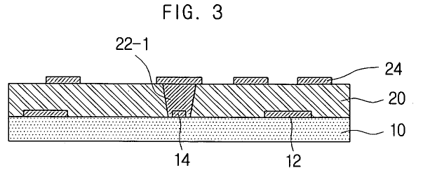

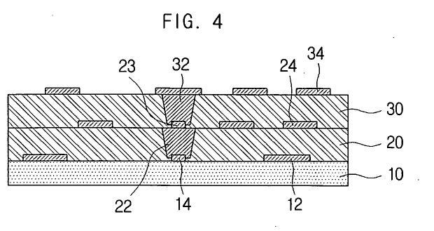

FIG. 2 through FIG. 4 are cross-sectional views of a printed circuit board according to an aspect of the present invention. In FIGS. 2 to 4 are illustrated a substrate 10, circuit patterns 12, 24, 34, pads 14, 23, a first insulation layer 20, a first via 22, a second insulation layer 30, and a second via 32.

The printed circuit board according to this particular embodiment may be structured to have the pad 14, which is formed at the lower surface of the first insulation layer 20, buried in the first via 22, which penetrates the first insulation layer 20 to implement interlayer connection.

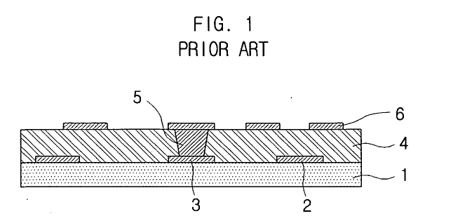

In the case of the printed circuit board according to the related art described above, referring to FIG. 1, the upper surface of the pad 3 is formed wider than the lower surface of the via 5, so that the pad 3 and via 5 are placed in contact across one surface only. With such an arrangement according to the related art, the via 5 and the pad 3 have to be formed to correspondingly wide areas, if a particular contact area is to be obtained between the via 5 and the pad 3, so that there is difficulty in implementing fine pitch.

In consideration of such difficulty, the present embodiment may have the pad 14 buried in the via 22, presenting a structure in which contact can be made not only by the upper surface of the pad 14 but also by the side of the pad 14. As a result, according to this embodiment, the same contact area can be secured with pad of a smaller size, compared to the case of the related art, whereby products can be implemented with higher densities in a more efficient manner. Furthermore, since a wider contact area can be obtained with pads of the same size, compared to the case of the related art, the reliability of the products may also be increased.

Those cases having the whole of the pad 14 buried in the first via 22, such as in the example illustrated in FIG. 3, may provide maximum contact area between the first via 22 and the pad 14, to implement an ideal structure. However, in consideration of manufacturing tolerances, etc., the pad 14 can be made to have just a portion thereof buried in the first via 22, as illustrated in FIG. 2.

Moreover, according to design requirements, a structure can be implemented with the vias 22, 32 and pads 14, 23 described above formed continuously across the structure, as in the example illustrated in FIG. 4.

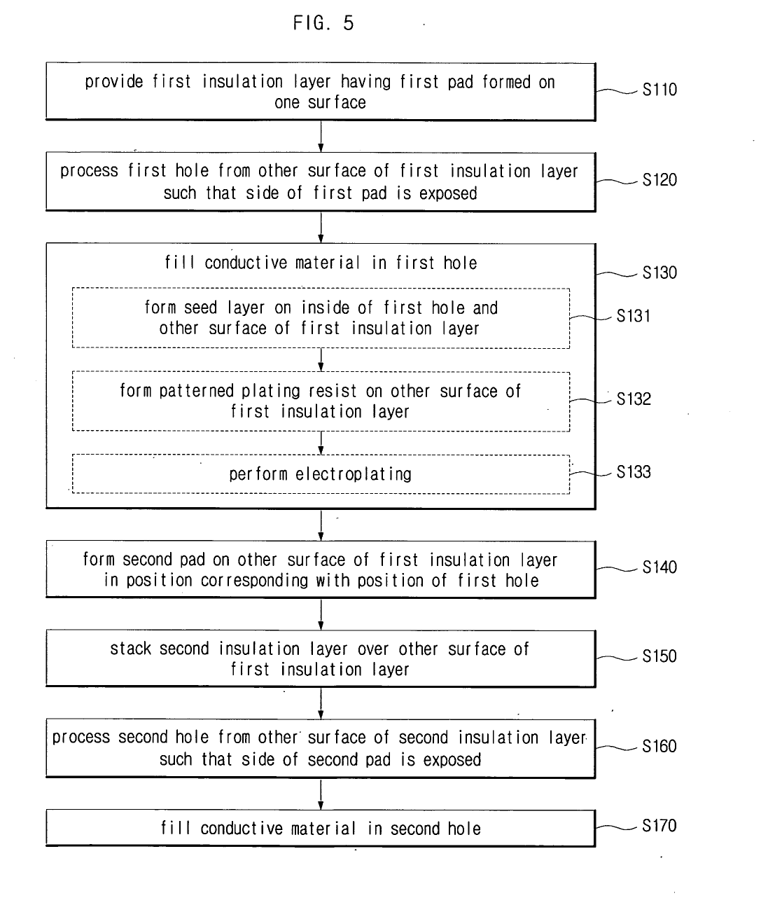

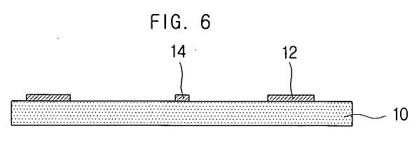

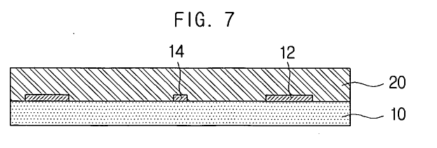

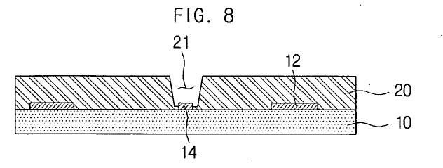

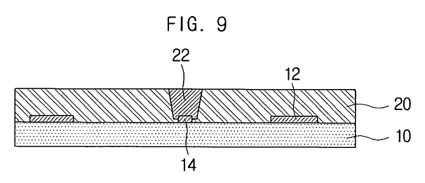

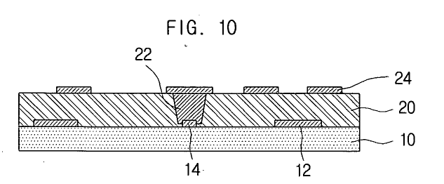

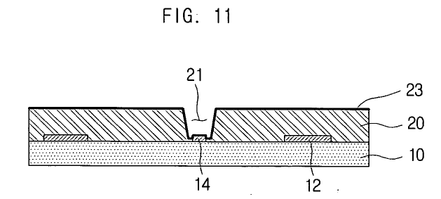

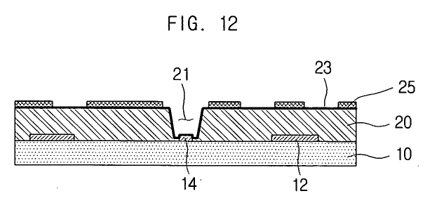

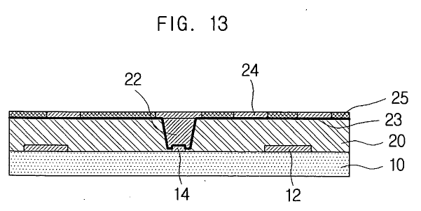

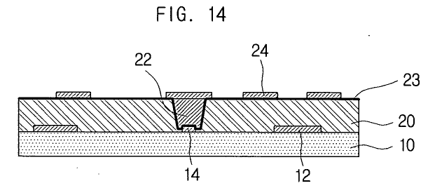

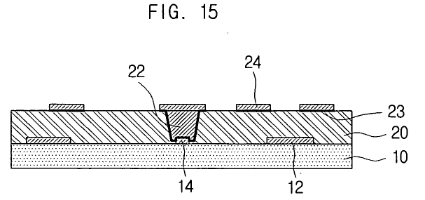

A manufacturing method will now be described below for the printed circuit board structured as above, with reference to FIG. 5 through FIG. 15. FIG. 5 is a flowchart illustrating a method of manufacturing a printed circuit board according to another aspect of the present invention, FIGS. 6 to 10 are cross-sectional views representing a flow diagram for a method of manufacturing a printed circuit board according to a first disclosed embodiment based on another aspect of the present invention, and FIGS. 11 to 15 are cross-sectional views representing a flow diagram for a method of manufacturing a printed circuit board according to a second disclosed embodiment based on another aspect of the present invention.

In FIGS. 5 to 15 are illustrated a substrate 10, circuit patterns 12, 24, a pad 14, a first insulation layer 20, a first hole 21, a first via 22, a seed layer 23, circuit patterns 12, 24, and a plating resist 25.

First, a first insulation layer 20 may be provided that has a circuit pattern 12 and a first pad 14 formed on one surface (S110), after which a first hole 21 may be processed from the other surface of the first insulation layer 20 such that the side of the first pad 14 is exposed (S120).

That is, onto an upper surface of a substrate 10 having a first pad 14 and a circuit pattern 12 formed thereon as illustrated in FIG. 6, a first insulation layer 20 can be stacked such that the first pad 14 and the circuit pattern 12 are buried in the first insulation layer 20, after which a first hole 21 can be processed, as illustrated in FIG. 8, such that the side of the first pad 14 is exposed. While it is apparent that any of various physical/chemical means can be employed in processing the first hole 21, this particular embodiment illustrates the case of using a laser drill, with which the processing depth can be efficiently controlled.

After thus processing the first hole 21, a conductive material may be filled in the first hole 21 (S130), as illustrated in FIG. 9, and then a circuit pattern 24 may be formed on an upper surface of the first insulation layer 20, as illustrated in FIG. 10.

With the side of the pad 14 exposed by the previous processes, filling the first hole 21 with conductive material allows the conductive material to be in contact not only with the upper surface of the pad 14, but also with the side. When the conductive material thus filled is cured, the structure may be obtained that has the pad 14 buried in the via 22.

Examples of possible methods for filling the first hole 21 with conductive material include methods of printing using metal ink and methods using electroless plating and electroplating, etc.

While the filling with conductive material and the forming of the circuit pattern 24 may be formed in sequential operations, as illustrated in FIG. 9 and FIG. 10, it is possible also to perform the operations simultaneously, as illustrated in FIGS. 11 to 15. This will be described in more detail as follows.

First, as illustrated in FIG. 11, a seed layer 23 may be formed on the inside of the first hole 21 and the upper surface of the first insulation layer 20 (S131), and as illustrated in FIG. 12, a patterned plating resist 25 may be formed on the upper surface of the first insulation layer 20 (S132). Then, as illustrated in FIG. 13, electroplating may be performed (S133). Afterwards, the plating resist 25 may be removed, as illustrated in FIG. 14, and flash etching may be performed, as illustrated in FIG. 15, whereby the forming of the circuit pattern 24 and the filling of the conductive material may be performed simultaneously.

Furthermore, by repeating the processes described above, the structure may be formed that has the vias 22, 32 and the pads 14, 23 formed continuously across the structure, as presented in this embodiment. One such example is illustrated in FIG. 4.

That is, a second pad 23 may be formed on the upper surface of the first insulation layer 20 in a position corresponding to the position of the first hole 21 (S140), and a second insulation layer 30 may be stacked on the upper surface of the first insulation layer 20 (S150), after which a second hole (not shown) may be processed from the other surface of the second insulation layer 30 such that the side of the second pad 23 is exposed (S160), and then a conductive material may be filled in the second hole (not shown) to form a second via 32 (S170).

The processing of the second hole (not shown) can be performed by a method that is substantially the same as the method described above for the processing of the first hole 21, and the filling of the second hole (not shown) with conductive material can be performed by a method that is substantially the same as the method described above for filling the first hole 21 with conductive material. As such, the descriptions for these processes will not be repeated.

According to certain embodiments of the invention as set forth above, all of or a portion of the pad can be buried in the via, to increase the contact area between the pad and via, whereby a printed circuit board can be provided that offers high reliability.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

Many embodiments other than those set forth above are encompassed within the scope of claims of the present invention.

What is claimed is:

1. A printed circuit board comprising:
a first insulation layer;
a first via penetrating the first insulation layer; and
a first pad formed on one surface of the first insulation layer and having a whole of or a portion of the first pad buried in the first via.

2. The printed circuit board of claim 1, further comprising:
a second pad formed on the other surface of the first insulation layer in a position corresponding with a position of the first via;
a second insulation layer stacked over the other surface of the first insulation layer; and
a second via penetrating the second insulation layer,
wherein a whole of or a portion of the second pad is buried in the second via.

3. A method of manufacturing a printed circuit board, the method comprising:
providing a first insulation layer having a first pad formed on one surface thereof;
processing a first hole from the other surface of the first insulation layer such that a side of the first pad is exposed; and
filling a conductive material in the first hole.

4. The method of claim 3, wherein filing the conductive material comprises:
forming a seed layer on an inside of the first hole and the other surface of the first insulation layer;
forming a patterned plating resist over the other surface of the first insulation layer; and
performing electroplating.

5. The method of claim 3, wherein a depth of the first hole is substantially equal to a depth of the first insulation layer.

6. The method of claim 3, further comprising:
forming a second pad on the other surface of the first insulation layer in a- position corresponding with a position of the first hole;
stacking a second insulation layer over the other surface of the first insulation layer;
processing a second hole from the other surface of the second insulation layer such that a side of the second pad is exposed; and
filling a conductive material in the second hole.

7. The method of claim 3, wherein processing the first hole is performed by laser drilling.
